(19) United States
(12) Patent Application Publication
(10) Pub. No.: US 2005/0024117 A1
(43) Pub. Date: Feb. 3, 2005

(54) Phase interpolator circuitry for reducing clock skew

(75) Inventors: Satoru Kubo, Kanagawa (JP); Toshikazu Otake, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 10/899,112

(22) Filed: Jul. 27, 2004

(30) Foreign Application Priority Data
Jul. 28, 2003 (JP) 281375/2003

(51) Int. Cl. H03K 3/00

(52) U.S. Cl. 327/258

(57) ABSTRACT

A phase interpolator circuitry is composed of a delay line, and a phase blender circuit. The delay line delays a first input clock signal to develop a delayed clock signal. The phase blender circuit includes a first inverter receiving the delayed clock signal, and a second inverter receiving a second input clock signal phased away from the first input clock signal. The outputs of the first and second inverters are commonly coupled together. The phase interpolator circuitry additionally includes at least one of constant current sources: first one connected between a power terminal of the first inverter and a power supply, second one connected between a ground terminal of the first inverter and ground, third one connected between a power terminal of the second inverter and a power supply, and fourth one connected between a ground terminal of the second inverter and ground.

### BACKGROUND OF THE INVENTION

1. Field of the Invention

The present invention is generally related to phase interpolator circuitries, more particularly, to skew reduction in phase interpolator circuitries suitable for multiphase clocks.

2. Description of the Related Art

Clock and data recovery is one of the widely known techniques used for high-speed data transmission. In a data transfer system adopting clock and data recovery, a receiver reproduces a synchronized clock signal from a data signal received from a transmitter using a clock generator, typically including a quartz oscillator and a frequency multiplier, such as a PLL (phase lock loop) circuit; the transmitter does not provide the receiver with any clock signal for achieving synchronization. A clock and data recovery technique eliminates a need for transmitting a high-frequency clock signal between a transmitter and a receiver, and thereby facilitates high-speed data transmission.

A clock and data recovery technique requires generating a high-frequency clock within a receiver for achieving high-speed data transmission; however, a receiver often experiences a difficulty in generating high-frequency clocks.

Using multiphase clocks, which designate a sequence of clock signals equally phased from each other, is one of the solutions for overcoming this difficulty. Each clock signal included in a sequence of multiphase clocks is allowed to have a low frequency, and this advantageously solves the high-frequency problem.

Nevertheless, significant requirements for multiphase clocks include reduced skew and jitter, and precisely controlled duty ratio. Specifically, skew, jitter and duty ratio of multiphase clocks are required to be controlled two to four times as precisely as the data rate of the data signal.

T. Saeki discloses a phase interpolator circuitry for reducing skew of multiphase clocks with simple circuit configuration in “A 1.3-Cycle Lock Time, Non-PLL/DLL Clock Multiplier Based on Direct Clock Cycle Interpolation for ‘Clock on Demand’”, IEEE Journal of Solid-State Circuits, vol. 35, No. 11, November 2000. FIG. 1 is a circuit diagram illustrating a 90°-phase interpolator circuitry, which is denoted by numeral 201. The phase interpolator circuitry 201 includes delay lines 101, 103, 105, and 107, and phase blender circuits 102, 104, 106, and 108. The delay lines 101, 103, 105, and 107 are composed of series-connected inverters, while the phase blender circuits 102, 104, 106, and 108 are composed of a pair of parallel-connected inverters, and an output inverter connected to the output of the parallel-connected inverters. The inverters within the delay lines 101, 103, 105, and 107 are denoted by numerals 101-n, 103-n, 105-n, and 107-n, and the inverters within the phase blender circuits 102-n, 104-n, 106-n, and 108-n.

The phase interpolator circuitry 201 achieves interpolation of a sequence of four input clocks IN1 to IN4 which are equally phased at intervals of 90° in an ideal situation. The ideal phases of the clocks IN1, IN2, IN3, and IN4 are defined as being 0 °, 90°, 180°, and 270°, respectively.

The operation of the circuitry is as follows. Ideally, the delay lines 101, 103, 105, and 107 is designed to provide a phase delay of 90°; the phase delay of the delay lines 101, 103, 105, and 107 is denoted by symbol α, hereinafter. The delay lines 101, 103, 105, and 107 delay the input clocks IN1 to IN4, and provides the delayed clocks, which are denoted by symbols IN1′ to IN4′, for the phase blenders 102, 104, 106, and 108, respectively. The phase blender 102 synthesizes the delayed clock IN1′ with the input clock IN2 to develop an output clock OUT1, which ideally has a phase of 90°. Correspondingly, phase blenders 104, 106, and 108 synthesize the delayed clocks IN2′, IN3′, and IN4′with the input clocks IN3, IN4, and IN1 to develop output clocks OUT2, OUT3, and OUT4, respectively.

Ideally, the phase of the output clock OUT1 is 90°; however, the actual phase of the output clock OUT1 is different from the ideal value due to the phase variances of the original input clocks IN1 to IN4 from the ideal phases, and the delay of the phase blender 102. Specifically, the actual phase of the output clock OUT1 is represented by the following formula (1-1):

$$\begin{matrix}{θ}^{OUT1} = \frac{( {0}^{°} + E0 + α ) + ( {90}^{°} + E90 )}{2} + β , \\ = \frac{2 ( {0}^{°} + α ) + E0 + E90}{2} + β , \\ = {0}^{°} + α + β + \frac{E0 + E90}{2} ,\end{matrix} \qquad Λ ( 1 - 1 )$$

where θ^{OUT1} is the phase of the output clock OUT1, α is the phase delay of the delay line 101, ideally 90°, β is the phase delay of the phase blender 102, EO is the phase error of the input clock INl, which is defined as the difference between the actual and ideal values of the phase of the input clock IN1, and E90 is the phase error of the input clock IN2. The formula (1-1) teaches that phase of the output clock OUT1 depends on the average of the phase errors of the input clocks IN1 and IN2.

Correspondingly, the phases of the output clocks OUT2, OUT3, and OUT4 are represented by the following formulas (1-2) to (1-4):

$$\begin{matrix}\begin{matrix}{θ}^{OUT2} = \frac{( {90}^{°} + E90 + α ) + ( {180}^{°} + E180 )}{2} + β , \\ = \frac{2 ( {90}^{°} + α ) + E90 + E180}{2} + β , \\ = {90}^{°} + α + β + \frac{E90 + E180}{2} ,\end{matrix} & Λ ( 1 - 2 ) \\ \begin{matrix}{θ}^{OUT3} = \frac{( {180}^{°} + E180 + α ) + ( {270}^{°} + E270 )}{2} + β , \\ = \frac{2 ( {180}^{°} + α ) + E180 + E270}{2} + β , \\ = {180}^{°} + α + β + \frac{E180 + E270}{2} ,\end{matrix} & Λ ( 1 - 3 ) \\ \begin{matrix}{θ}^{OUT4} = \frac{( {270}^{°} + E270 + α ) + ( {0}^{°} + E0 )}{2} + β , \\ = \frac{2 ( {270}^{°} + α ) + E270 + E0}{2} + β , \\ = {270}^{°} + α + β + \frac{E270 + E0}{2} ,\end{matrix} & Λ ( 1 - 4 )\end{matrix}$$

where θ^{OUT2}, θ^{OUT3}, and θ^{OUT4} are the phases of the output clocks OUT2, OUT3 and OUT4, E180 is the phase error of the input clock IN3, and E270 is the phase error of the input clock IN4.

The fourth terms of the formulas (1-1) to (1-4) indicate that the phase interpolator circuitry 201 does not achieve interpolations between two input clocks phased from each other by 180°.

In order to achieve improved interpolation, as illustrated in FIG. 2, an 180° interpolator circuitry 202 may be connected to the outputs of the 90° phase interpolator circuitry 201. The configuration of the 180° interpolator circuitry 202 is almost identical to that of the 90° phase interpolator circuitry 201 except for that the delay lines 101, 103, 105, and 107, which have a phase delay of α, are replaced with delay lines 101′, 103′, 105′, and 107′ which have a phase delay of 2α. The delay lines 101′, 103′, 105′, and 107′ receive the clocks OUT1 to OUT4 from the 90° phase interpolator circuitry 201, respectively. The phase blender circuit 102 of the 180° phase interpolator circuitry 202 synthesizes the clock received from the delay line 101′ with the clock OUT3 to develop an output clock OUT1′, while the phase blender circuit 106 synthesizes the clock received from the delay line 105′ with the clock OUT1 to develop an output clock OUT3′. Correspondingly, the phase blender circuit 104 synthesizes the clock received from the delay line 103′ with the clock OUT4 to develop an output clock OUT2′ within the 180° phase interpolator circuitry 202, while the phase blender circuit 108 synthesizes the clock received from the delay line 107′ with the clock OUT2 to develop an output clock OUT4′.

The phases of the output clock OUT1′ to OUT4′ are represented by the following formulas (2-1) to (2-4):

$$\begin{matrix}\begin{matrix}{θ}^{{OUT1}^{′}} = \frac{( {θ}^{OUT1} + 2 α ) + {θ}^{OUT3}}{2} + β , \\ = \frac{( {0}^{°} + α + β + \frac{E0 + E90}{2} + 2 α ) + ( {180}^{°} + α + β + \frac{E180 + E270}{2} )}{2} + β , \\ = {0}^{°} + 3 α + 2 β + \frac{E0 + E90 + E180 + E270}{4} ,\end{matrix} & Λ ( 2 - 1 ) \\ \begin{matrix}{θ}^{{OUT2}^{′}} = \frac{( {θ}^{OUT2} + 2 α ) + {θ}^{OUT4}}{2} + β , \\ = \frac{( {90}^{°} + α + β + \frac{E90 + E180}{2} + 2 α ) + ( {270}^{°} + α + β + \frac{E270 + E0}{2} )}{2} + β , \\ = {90}^{°} + 3 α + 2 β + \frac{E0 + E90 + E180 + E270}{4} ,\end{matrix} & Λ ( 2 - 2 ) \\ \begin{matrix}{θ}^{{OUT3}^{′}} = \frac{( {θ}^{OUT3} + 2 α ) + {θ}^{OUT1}}{2} + β , \\ = \frac{( {180}^{°} + α + β + \frac{E180 + E270}{2} + 2 α ) + ( {0}^{°} + α + β + \frac{E0 + E90}{2} )}{2} + β , \\ = {180}^{°} + 3 α + 2 β + \frac{E0 + E90 + E180 + E270}{4} ,\end{matrix} & Λ ( 2 - 3 ) \\ \begin{matrix}{θ}^{{OUT4}^{′}} = \frac{( {θ}^{OUT4} + 2 α ) + {θ}^{OUT2}}{2} + β , \\ = \frac{( {270}^{°} + α + β + \frac{E270 + E0}{2} + 2 α ) + ( {90}^{°} + α + β + \frac{E90 + E180}{2} )}{2} + β , \\ = {270}^{°} + 3 α + 2 β + \frac{E0 + E90 + E180 + E270}{4} ,\end{matrix} & Λ ( 2 - 4 )\end{matrix}$$

where θ^{OUT1′}, θ^{OUT2′}, θ^{OUT3′}, and θ^{OUT4′} are the phases of the output clocks OUT1′, OUT2′, OUT3′and OUT4′.

The formulas (2-1) to (2-4) indicates that the phase of the output clocks OUT1′, OUT2′, OUT3′ and OUT4′ commonly depends on the average of the phase errors of the input clocks IN1 to IN4, and thus, the output clocks OUT1′, OUT2′, OUT3′ and OUT4′ are free from clock skews.

Although being effective for reducing skew, the resultant output clocks obtained from the circuitries shown in FIGS. 1 and 2 may undesirably exhibit unsmooth waveforms, including stepped waveforms, when the input clocks have reduced rising and/or falling times.

Additionally, the conventional circuitries may suffer from insufficient interpolation due to the inevitable manufacture variation, and the changes in the operation temperature and the power supply voltage; these causes undesirable changes in the phase delays of the delay lines and the phase blender circuits.

Furthermore, recent requirements include generating multiphase clocks having higher frequencies, and this necessitates reduction in the undesirable changes in the phase delays of the delay lines and the phase blender circuits.

Therefore, there is a need for providing a phase interpolation circuitry which improves smoothness in the waveforms of the resultant multiphase clocks, and achieves stable interpolation through being free from the influence of the manufacture variation, and the changes in the operation temperature and the power supply voltage.

### SUMMARY OF THE INVENTION

The present invention generally addresses an improved phase interpolation architecture.

Specifically, one object of the present invention is to provide a phase interpolation circuitry for achieving stabilized interpolation of multiphase clocks with reduced clock skews.

Another object of the present invention is to provide a phase interpolation circuitry that improves smoothness in the waveforms of the resultant multiphase clocks.

In an aspect of the present invention, a phase interpolator circuitry is composed of a delay line, a phase blender circuit, at least one of first to fourth constant current sources. The delay line delays a first input clock signal to develop a delayed clock signal. The phase blender circuit includes a first inverter receiving the delayed input clock signal, and a second inverter receiving a second input clock signal phase away from the first input clock signal. The outputs of the first and second inverters are commonly coupled together. The first constant current source is connected between a power terminal of the first inverter and a power supply. The second constant current source is connected between a ground terminal of the first inverter and ground. The third constant current source is connected between a power terminal of the second inverter and a power supply. Finally, the fourth constant current source is connected between a ground terminal of the second inverter and ground.

The first constant current source preferably develops a pull-up current through the first inverter so that a rise time of the first inverter is increased compared to an intrinsic rise time of the first inverter.

Correspondingly, the second constant current source preferably develop a pull-down current through the first inverter so that a fall time of the first inverter is increased compared to an intrinsic fall time of the first inverter.

Furthermore, the third constant current source preferably develops a pull-up current through the second inverter so that a rise time of the second inverter is increased compared to an intrinsic rise time of the second inverter.

It is also preferable that the fourth constant current source develops a pull-down current through the second inverter so that a fall time of the second inverter is increased compared to an intrinsic fall time of the second inverter.

The first constant current source preferably has a drive ability smaller than that of a pull-up transistor within the first inverter.

Correspondingly, the second constant current source preferably has a drive ability smaller than that of a pull-down transistor within the first inverter.

Furthermore, the third constant current source preferably has a drive ability smaller than that of a pull-up transistor within the second inverter.

It is also preferable that the fourth constant current source has a drive ability smaller than that of a pull-down transistor within the second inverter.

When the delay line includes series-connected inverters, the delay line further includes pull-up constant current sources respectively connected between power terminals of the series-connected inverters and a power supply. The pull-up constant current sources develop pull-up currents through the series-connected inverters, respectively. In a preferred embodiment, the pull-up currents are variable.

It is also preferable that the delay line further includes pull-down constant current sources respectively connected between ground terminals of the series-connected inverters and ground. The pull-down constant current sources develop pull-down currents through the series-connected inverters, respectively. In a preferred embodiment, the pull-down currents are variable.

In one embodiment, the phase blender circuit further includes a third inverter having an input connected to the commonly coupled outputs of the first and second inverters. In this case, it is preferable that the phase blender circuit further includes a fifth constant current source connected between a power terminal of the third inverter and a power supply. It is also preferable that the phase blender circuit further includes a sixth constant current source connected between a ground terminal of the third inverter and ground.

The first and second input clock signals may be phased from each other by 360°/2ⁿ, n being an integer.

### BRIEF DESCRIPTION OF THE DRAWINGS

FIG. 1 is a circuit diagram illustrating a conventional phase interpolator circuitry;

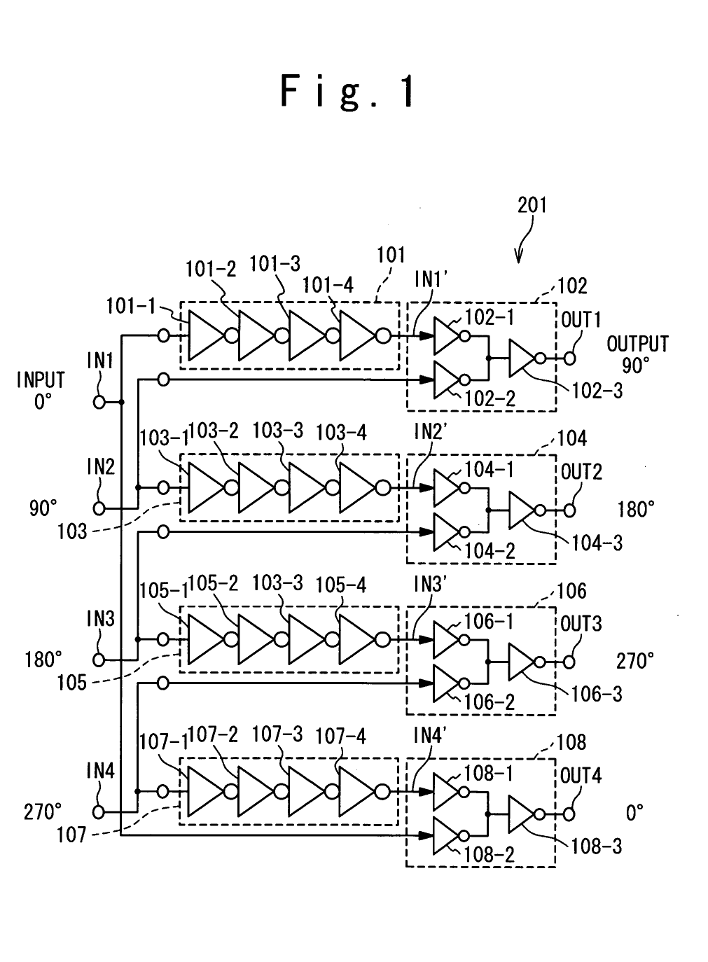

FIG. 2 is a circuit diagram illustrating another conventional phase interpolator circuitry;

FIG. 3 is a circuit diagram illustrating a phase interpolator circuitry in a first embodiment of the present invention;

FIG. 4 is a circuit diagram illustrating a phase blender circuit in the first embodiment;

FIG. 5 is a circuit diagram illustrating an exemplary architecture of constant current sources in the first embodiment;

FIG. 6 is a circuit diagram illustrating a phase interpolator circuitry in an alternative embodiment;

FIG. 7 is a circuit diagram illustrating a phase interpolator circuitry in another alternative embodiment;

FIG. 8 is a circuit diagram illustrating a phase interpolator circuitry in a second embodiment of the present invention;

FIG. 9 is a circuit diagram illustrating a phase interpolator circuitry in an alternative embodiment;

FIG. 10 is a circuit diagram illustrating a phase interpolator circuitry in another alternative embodiment;

FIG. 11 is a circuit diagram illustrating a phase interpolator circuitry in a third embodiment of the present invention;

FIG. 12 is a circuit diagram illustrating a phase interpolator circuitry in an alternative embodiment;

FIG. 13 is a circuit diagram illustrating a phase interpolator circuitry in another alternative embodiment;

FIG. 14 is a circuit diagram illustrating a phase interpolator circuitry in a fourth embodiment of the present invention;

FIG. 15 is a circuit diagram illustrating a phase interpolator circuitry in an alternative embodiment;

FIG. 16 is a circuit diagram illustrating a phase interpolator circuitry in another alternative embodiment;

FIG. 17 is a circuit diagram illustrating a phase interpolator circuitry in a fifth embodiment of the present invention;

FIG. 18 is a circuit diagram illustrating a phase interpolator circuitry in an alternative embodiment;

FIG. 19 is a circuit diagram illustrating a phase interpolator circuitry in another alternative embodiment; and

FIG. 20 is a circuit diagram illustrating an exemplary architecture of constant current sources in the fourth embodiment.

### DESCRIPTION OF THE PREFERRED EMBODIMENTS

Preferred embodiments of the present invention are described below in detail with reference to the attached drawings.

### First Embodiment

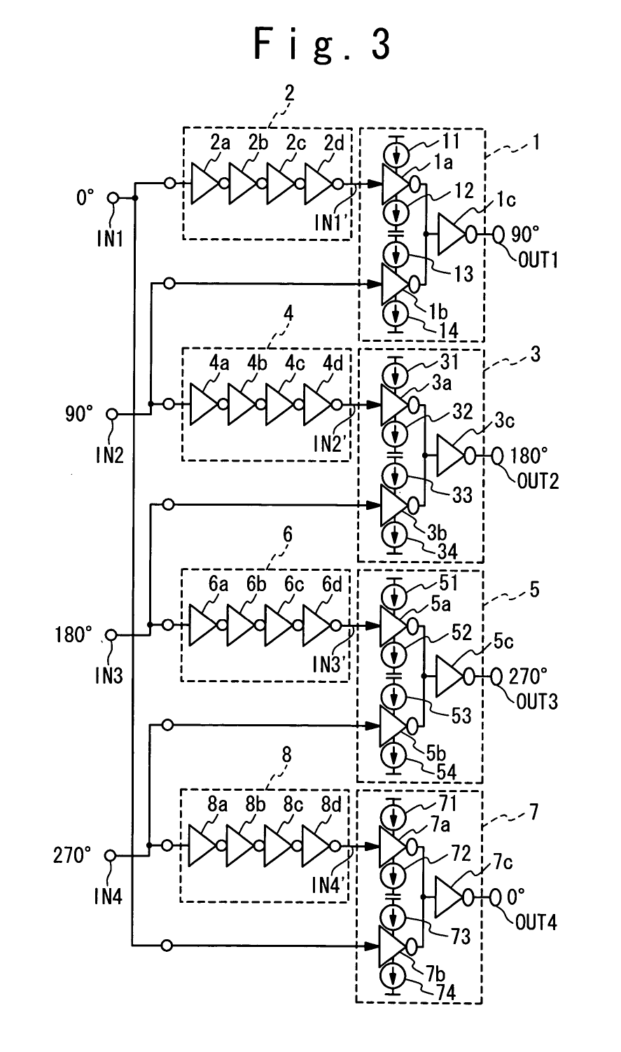

In a first embodiment, as shown in FIG. 3, a phase interpolation circuitry for multiphase clocks is composed of four delay lines 2, 4, 6, and 8, and four phase blender circuits 1, 3, 5, and 7. The delay lines 2, 4, 6, and 8 are composed of series-connected inverters. In FIG. 3, the inverters within the delay line 2 are denoted by numerals 2a through 2d, the inverters within the delay line 4 are denoted by numerals 4a through 4d, the inverters within the delay line 6 are denoted by numerals 6a through 6d, and the inverters within the delay line 8 are denoted by numerals 8a through 8d.

The delay lines 2, 4, 6, and 8 receives input clock signals IN1, IN2, IN3, and IN4, which are equally phased at constant intervals of 90° in an ideal state; the ideal phases of the input clock signals IN1, IN2, IN3, and IN4 are defined as being 0°, 90, 180°, and 270°, respectively. The delay lines 2, 4, 6, and 8 provide a delay of 90° for the input clock signals IN1, IN2, IN3, and IN4. The delayed clock signals, which are denoted by numerals IN1′, IN2′, IN3′, and IN4′, are inputted to the phase blender circuits 1, 3, 5, and 7.

The phase blenders 1, 3, 5, and 7 synthesize the delayed clock signals IN1′, IN2′, IN3′, and IN4′ with the original clock signals IN2, IN3, IN4, and IN1 to develop output clock signals OUT1, OUT2, OUT3, and OUT4, respectively.

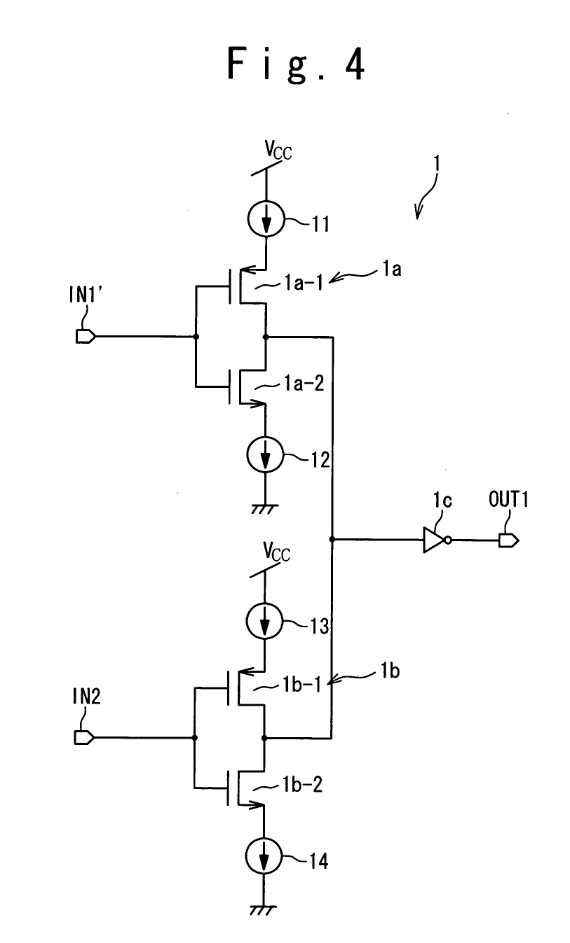

Specifically, the phase blender 1 includes parallel-connected inverters 1a, and 1b, and an output inverter lc having an input connected to outputs of the inverters 1a, and 1b. The power terminal of the inverter 1a is connected to a power supply through a constant current source 11, and the ground terminal of the inverter 1a is connected to ground through a constant current source 12. More specifically, as shown in FIG. 4, the constant current source 11 develops a constant pull-up current through a pull-up transistor 1a-1 within the inverter 1a, while the constant current source 12 develops a constant pull-down current through a pull-down transistor 1a-2. In a preferred embodiment, a PMOS transistor is used as the pull-up transistor 1a-1, and an NMOS transistor is used as the pull-down transistor 1a-2. Correspondingly, the power terminal of the inverter 1b is connected to a power supply through a constant current source 13, and the ground terminal of the inverter 1b is connected to ground through a constant current source 14. The constant current source 13 develops a pull-up current through a pull-up transistor 1b-1 within the inverter 1b, while the constant current source 14 develops a pull-down current through a pull-down transistor 1b-2.

Referring back to FIG. 3, the configuration of the phase blenders 3, 5, and 7 are identical to the phase blender 1. The phase blender 3 is composed of inverters 3a, 3b, and 3c and constant current sources 31 to 34. The phase blender 5 is composed of inverters 5a, 5b, and 5c and constant current sources 51 to 54. Finally, the phase blender 7 is composed of inverters 7a, 7b, and 7c and constant current sources 71 to 74.

The constant current sources 11 to 14, 31 to 34, 51 to 54, and 71 to 74 are important for achieving stabilized interpolation of the clock signals IN1 to IN4 using the phase blender circuits 1, 3, 5, and 7.

For the phase blender circuit 1, for example, the constant current sources 11 to 14 effectively stabilize the delay times of the inverters 1a and 1b within the phase blender circuits 1, and thereby effectively achieves stabilized interpolation of the clock signals IN1 and IN2.

Specifically, the constant current source 11 regulates the pull-up current through the inverter 1a to a desired value, and thereby stabilizes the rise time of the output of the inverter 1a. Correspondingly, the constant current source 12 regulates the pull-down current through the inverter 1a to a desired value, and thereby stabilizes the fall time of the output of the inverter 1a. This results in stabilization of the delay time of the inverter 1a.

The same goes for the constant current sources 13 and 14. The constant current source 13 stabilizes the rise time of the output of the inverter 1b, and the constant current source 14 stabilizes the fall time of the output of the inverter 1b. Accordingly, the constant current sources 13 and 14 effectively stabilize the delay time of the inverter 1b.

Stabilization of the delay times of the inverters 1a and 1b leads to stabilized interpolation between the clock signals IN1 and IN2.

Correspondingly, the constant current sources 31 to 34, 51 to 54, and 71 to 74 effectively achieves stabilized interpolations between the clock signals IN2 and IN3, between the clock signals IN3 and IN4, and between the clock signals IN4 and IN1.

In a preferred embodiment, the constant current sources 11 to 14 function as current limiters for increasing the rise and fall times of the inverters 1a and 1b above the intrinsic rise times thereof; the intrinsic rise times are defined as the rise times of the inverter outputs for the case when the power terminals of the inverters 1a and 1b are directly connected to power supplies. Such configuration effectively achieves smoothed waveforms of the output clock signals OUT1. The increased rise times of the inverters 1a and 1b smooth the leading edge waveforms of the clock signals outputted from the inverters 1a and 1b. Correspondingly, the increased fall times of the inverters 1a and 1b smooth the trailing edge waveforms of the clock signals outputted from the inverters 1a and 1b. This avoids the stepped waveforms being exhibited on the output clock signal OUT1.

In other words, as shown in FIG. 4, the constant current source 11 regulates the pull-up current through the pull-up transistor 1a-l below the maximum current allowable from the driving ability of the pull-up transistor 1a-1; the driving ability of the constant current source 11 is smaller than that of the pull-up transistor 1a-1. Correspondingly, the driving ability of the constant current source 12 is smaller than that of the pull-down transistor 1a-2.

The same goes for the constant current sources 13 and 14. The driving abilities of the constant current sources 13 and 14 are smaller than those of the pull-up and pull-down transistors 1b-1, and 1b-2, respectively.

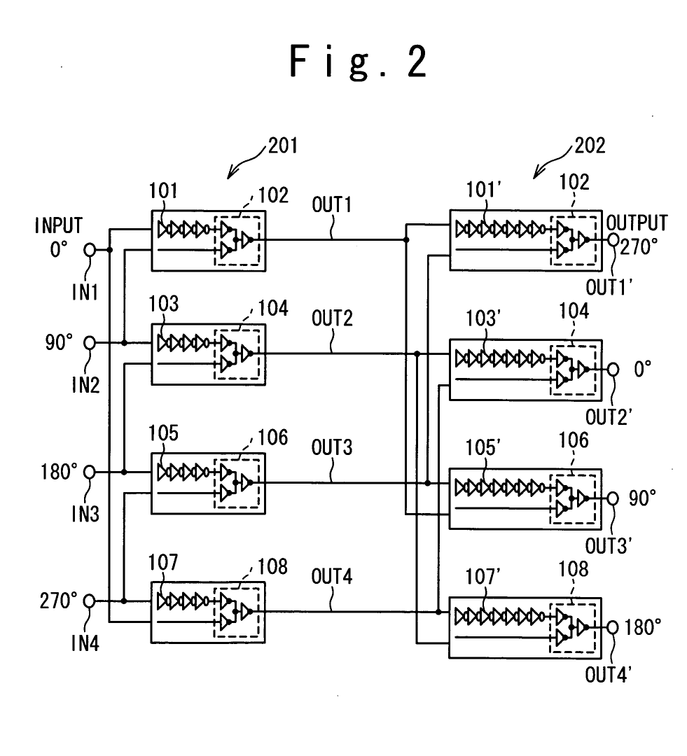

In order to achieve improved interpolation, another clock delivery circuit having the phase delay of the delay lines modified to 180° may be connected to the outputs of the clock delivery circuit of FIG. 3 in the same fashion as the circuitry shown in FIG. 2. This effectively achieves interpolations between the clock signals phased at intervals of 180°.

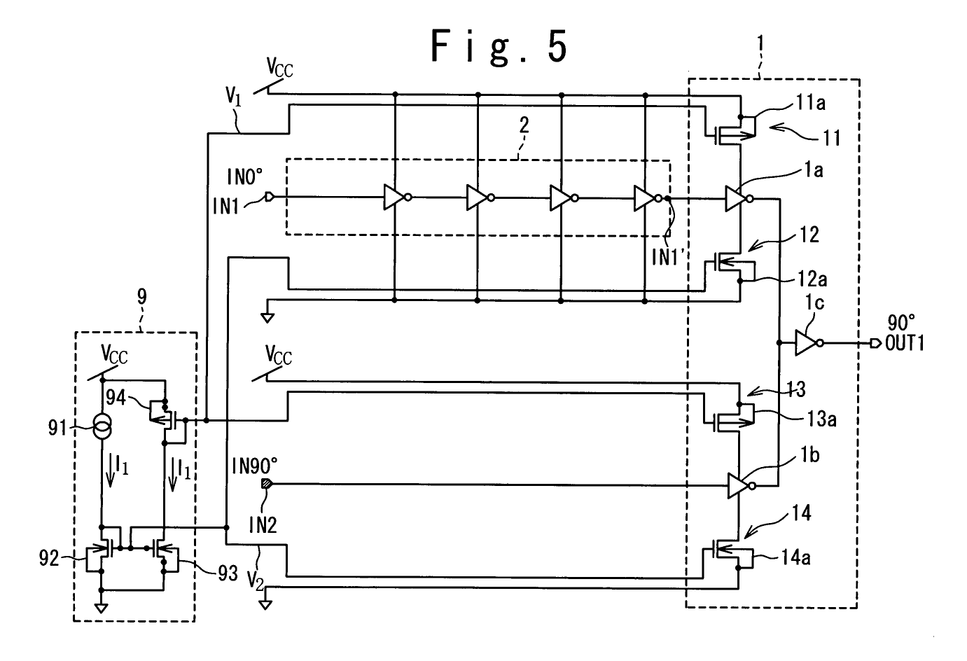

FIG. 5 is a circuit diagram of a preferred configuration of the phase blender circuit 1. In a preferred embodiment, the constant current sources 11 and 13 include PMOS transistors 11a and 13a whose gate voltages are regulated to a stabilized voltage V₁, while the constant current sources 12 and 14 include NMOS transistors 12a and 14a whose gate voltages are regulated to a stabilized voltage V₂. The PMOS transistors 11a and 13a are connected between power supplies and the power terminals of the inverters 1a and 1b, and the NMOS transistors 12a and 14a are connected between ground and the ground terminals of the inverters 1a and 1b.

The stabilized voltages V₁ and V₂ are developed by a stabilized voltage source 9. The stabilized voltage source 9 includes a constant current source 91, NMOS transistors 92 and 93, and a PMOS transistor 94. The sources of the NMOS transistors 92 and 93 are commonly connected to ground, and the gates of the NMOS transistors 92 and 93 are commonly coupled together.

Additionally, the drain of the NMOS transistor 92 is connected to the gate thereof. The drain of the NMOS transistor 93 is connected to a drain of The PMOS transistor 94. The drain of the PMOS transistor 94 is also connected to the gate thereof. The source of the PMOS transistor 94 is connected to a power supply.

The stabilized voltage source 9 operates as described in the following. The constant current source 91 develops a constant current I₁ through the NMOS transistor 92. The constant current I₁ develops the stabilized voltage V₂ on the gate of the NMOS transistor 92. The NMOS transistor 92 and the NMOS transistors 12a and 14a constitute current mirrors, and therefore stabilized currents identical to or proportional to the constant current I₁ are developed through the NMOS transistors 12a and 14a. Additionally, the NMOS transistor 92 and the NMOS transistor 93 constitute another current mirror, and therefore a current identical to the constant current I₁ is developed through the PMOS transistor 94. The constant current through the PMOS transistor 94 develops the stabilized voltage V₁ on the gate of the PMOS transistor 94. The PMOS transistor 94 and the PMOS transistors 11a and 11a constitute current mirrors, and therefore stabilized currents identical to or proportional to the constant current I₁ are developed through the PMOS transistors 11a and 13a.

An advantageous feature of the stabilized voltage source 9 is that the stabilized voltage source 9 is almost free from the influence of the manufacture variation, and the changes in the operation temperature and the power supply voltage. The fact that the stabilized voltage source 9 adopts the current mirror architecture effectively allows the stabilized voltage source 9 to be self-controlled, and thereby automatically cancels the influences of the undesirable manufacture variance and the changes in the operation temperature and the power supply voltage. This effectively stabilizes the voltages V₁ and V₂, and thereby stabilizes the pull-up and pull-down currents of the inverters 1a and 1b to desired values. The stabilization of the pull-up and pull-down currents of the inverters 1a and 1b is preferable for the stable operation of the phase blender circuit 1.

The configuration shown in FIG. 5 may apply to the remaining phase blender circuit 3, 5, and 7. In this case, the stabilized voltage source 9 may be shared by all the phase blender circuit 1, 3, 5, and 7.

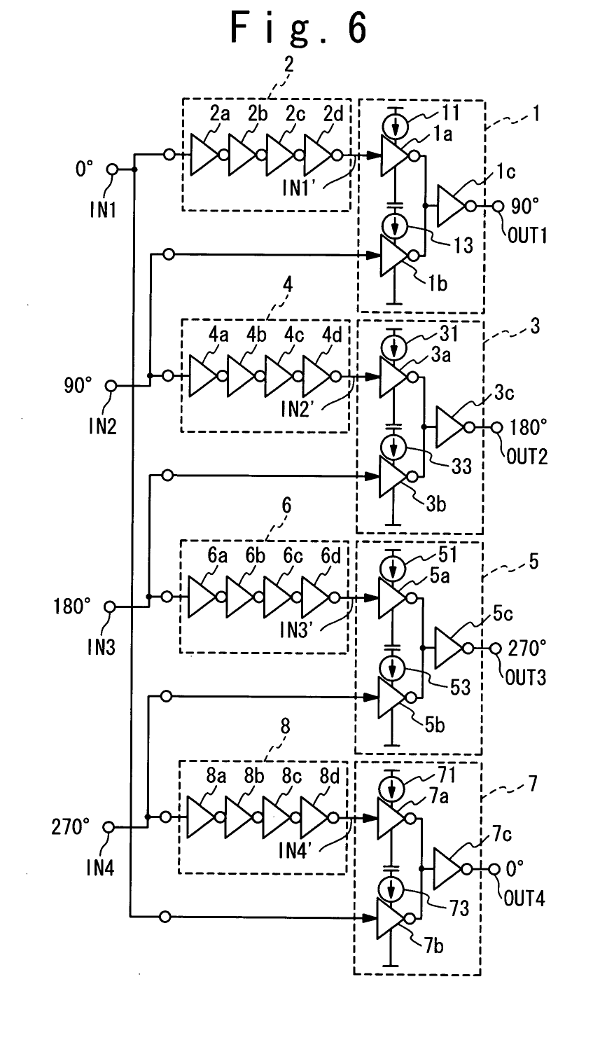

In an alternative embodiment, as shown in FIG. 6, the constant current sources 12, 14, 32, 34, 52, 54, 72, and 74, which are used for developing the pull-down currents, may be removed from the phase blender circuits 1, 3, 5, and 7. In this case, the ground terminals of the inverters 1a, 1b, 3a, 3b, 5a, 5b, 7a, and 7b are directly connected to ground. Although not stabilizing the fall times of the inverters, this architecture is still effective for stable control of the rise times of the inverters, and thus useful for stabilizing the interpolations of the clock signals IN1 to IN4.

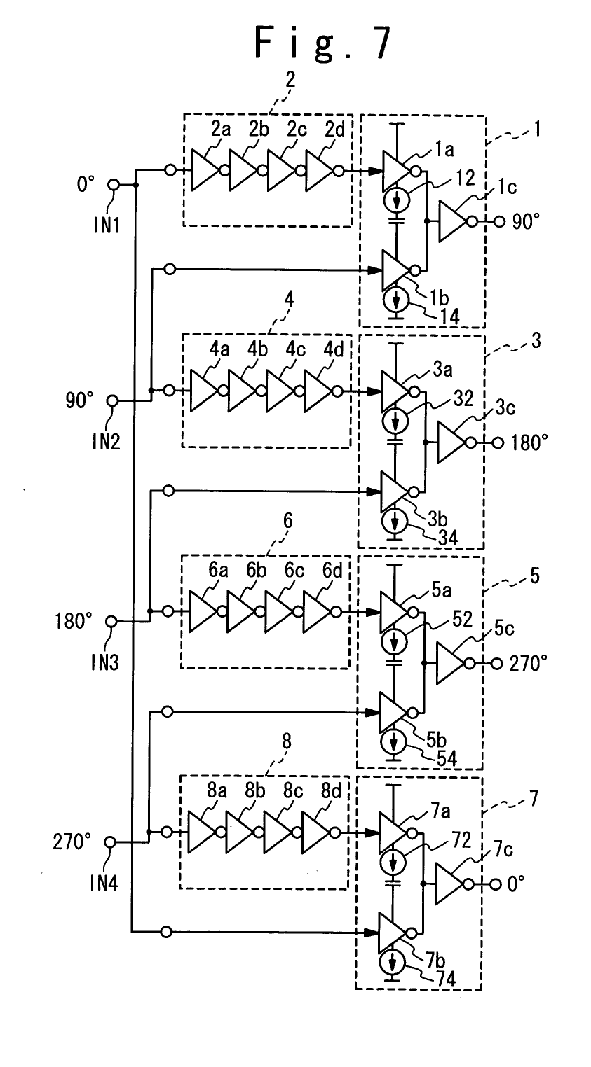

In another alternative embodiment, as shown in FIG. 7, the constant current sources 11, 13, 31, 33, 51, 53, 71, and 73, which are used for developing the pull-up currents, may be removed from the phase blender circuits 1, 3, 5, and 7 in place of the constant current sources 12, 14, 32, 34, 52, 54, 72, and 74. This architecture is still effective for stable control of the fall times of the inverters, and thus useful for stabilizing the interpolations of the clock signals IN1 to IN4.

### Second Embodiment

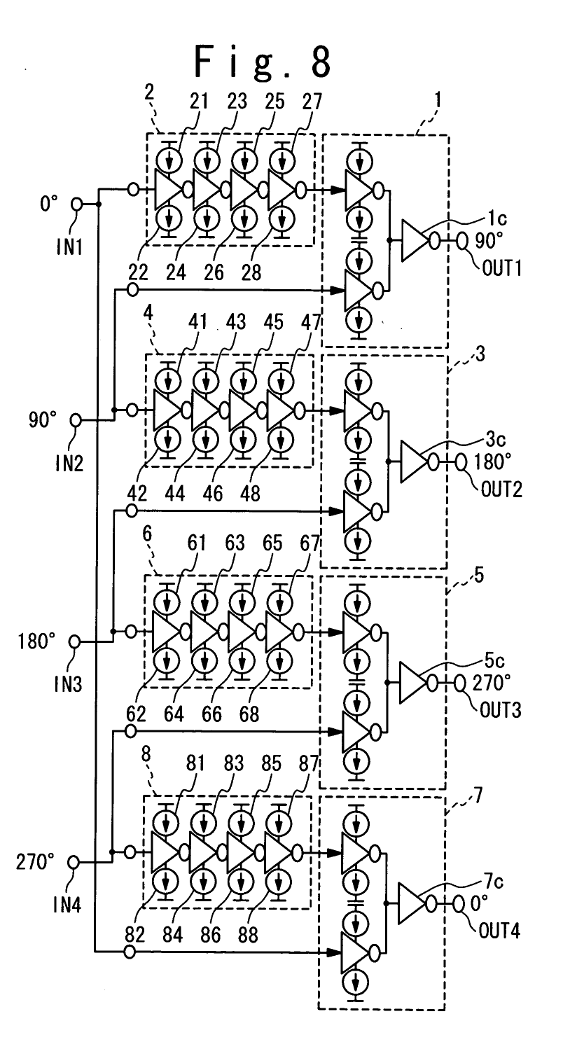

In a second embodiment, as shown in FIG. 8, constant current sources, denoted by numerals 21 to 28, 41 to 48, 61 to 68, and 81 to 88, are additionally connected to the power and ground terminals of the serial-connected inverters within the delay lines 2, 4, 6, and 8. The constant current sources 21 to 28, 41 to 48, 61 to 68, and 81 to 88 effectively regulates the pull-up and pull-down currents, that is, the rise/fall times of the serial-connected inverters within the delay lines 2, 4, 6, and 8, and thereby stabilize the delay times of the delay lines 2, 4, 6, and 8 against the undesirable manufacture variance and the changes in the operation temperature and the power supply voltage. This effectively reduces the clock skews between the output clock signals OUT1 to OUT4.

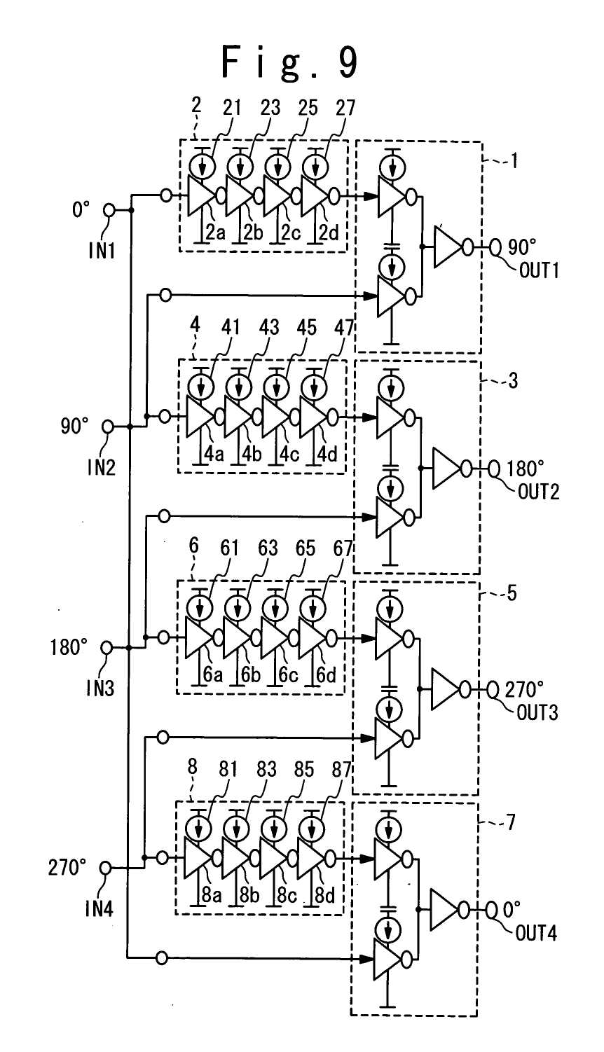

In an alternative embodiment, as shown in FIG. 9, the constant current sources between the serial-connected inverters and ground, denoted by the numerals 22, 24, 26, 28, 42, 44, 46, 48, 62, 64, 66, 68, 82, 84, 86, and 88, may be removed from the delay lines 2, 4, 6, and 8. Although being ineffective for regulating the fall times, this architecture effectively regulates the rise times of the serial-connected inverters, and thereby stabilizes the delay times of the delay lines 2, 4, 6, and 8.

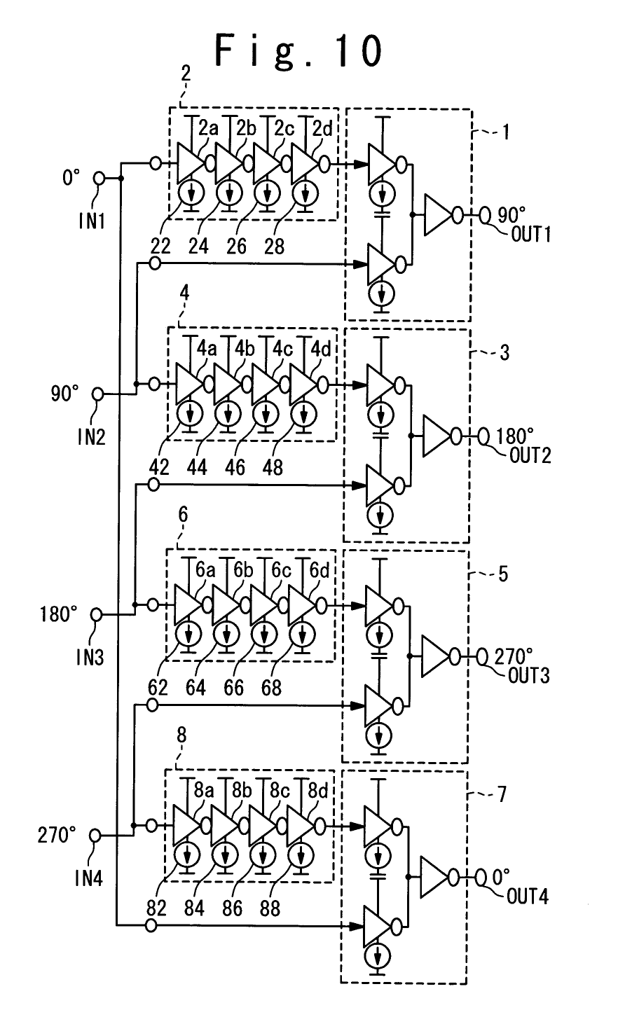

In another alternative embodiment, as shown in FIG. 10, the constant current sources between the serial-connected inverters and the power supply, denoted by the numerals 21, 23, 25, 27, 41, 43, 45, 47, 61, 63, 65, 67, 81, 83, 85, and 87, may be removed from the delay lines 2, 4, 6, and 8 in place of the constant current sources 22, 24, 26, 28, 42, 44, 46, 48, 62, 64, 66, 68, 62, 64, 66, and 68. Although being ineffective for regulating the rise times of the serial-connected inverters, this architecture still effectively regulates the fall times, and thereby stabilizes the delay times of the delay lines 2, 4, 6, and 8.

### Third Embodiment

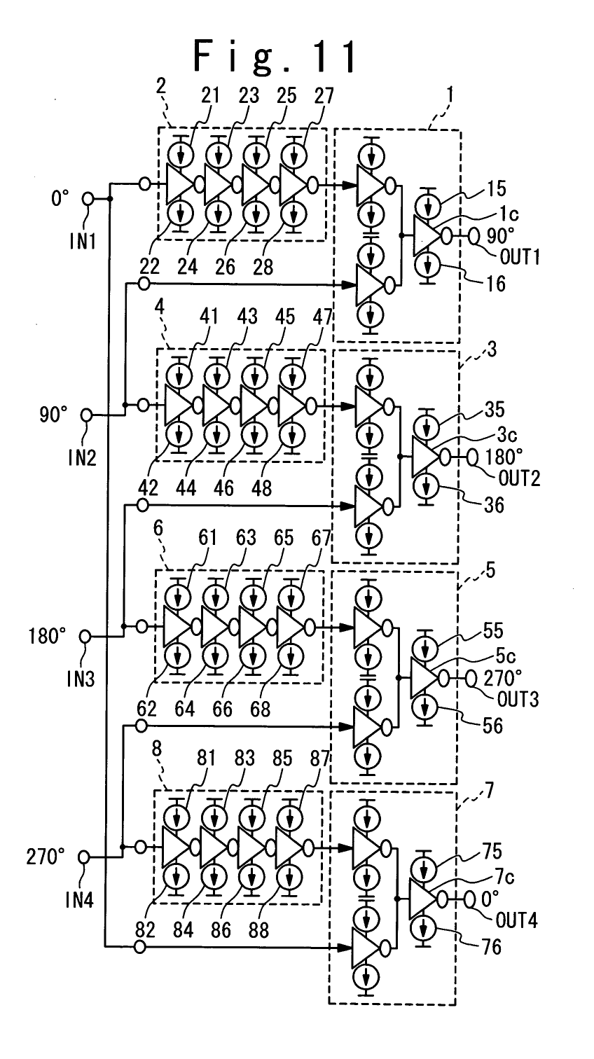

In a third embodiment, as shown in FIG. 11, each of the phase blender circuits 1, 3, 5, 7 additionally include a pair of constant current sources, one disposed between the power terminal of the output inverter and the power supply, and the other between the ground terminal and ground; the constant current sources connected to the power terminals of the output inverters are denoted by numerals 15, 35, 55, and 75, and the constant current sources connected to the ground terminals are denoted by numerals 16, 36, 56, and 76.

The additional constant current sources 15, 16, 35, 36, 55, 56, 75, and 76 effectively regulate the pull-up and pull-down currents, that is, the rise/fall times of the output inverters 1c, 3c, 5c, and 7c within the phase blender circuit 1, 3, 5, and 7, and thereby stabilize the delay times of the phase blender circuit 1, 3, 5, and 7 against the undesirable manufacture variance and the changes in the operation temperature and the power supply voltage. This effectively reduces the clock skews between the output clock signals OUT1 to OUT4.

The architecture shown in FIG. 11, in which all the inverters are connected to the power supply and ground through the constant current sources, is also effective for reducing influences of the power noise on the output clock signals OUT1 to OUT4 due to the increased impedance between the inverters and the power supply and that between the inverters and ground.

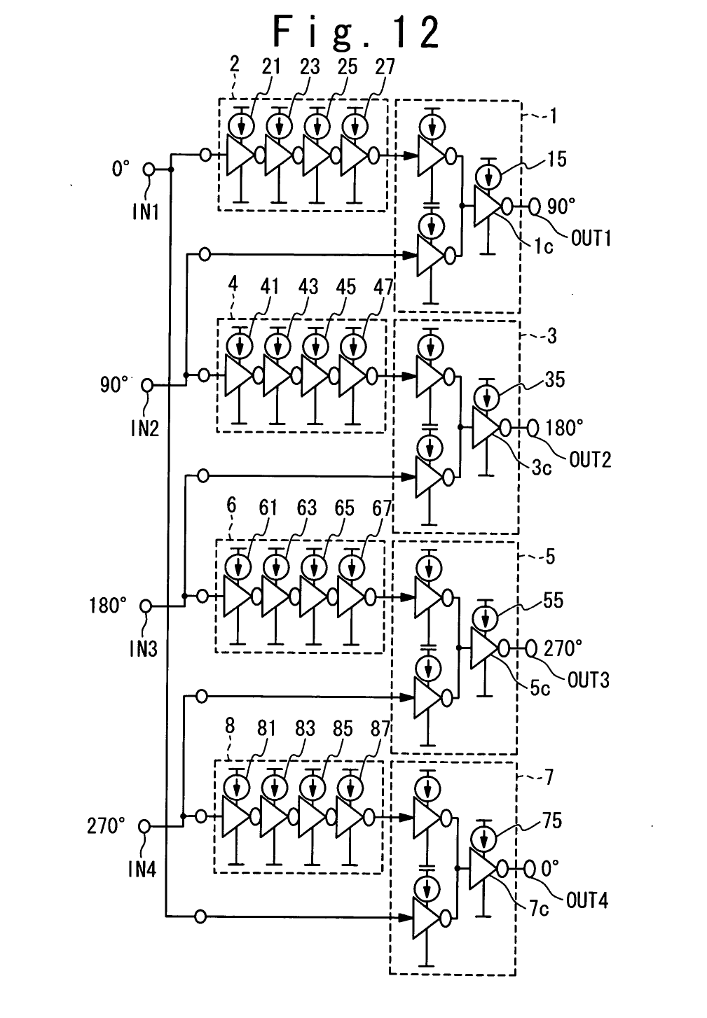

In an alternative embodiment, as shown in FIG. 12, the constant current sources between the output inverters and ground, denoted by numerals 16, 36, 56, and 76, may be removed from the phase blender circuits 1, 3, 5, and 7. Although being ineffective for regulating the fall times of the output inverters 1c, 3c, 5c, and 7c, this architecture still effectively regulates the rise times, and thereby stabilizes the delay times of the phase blender circuits 1, 3, 5, and 7.

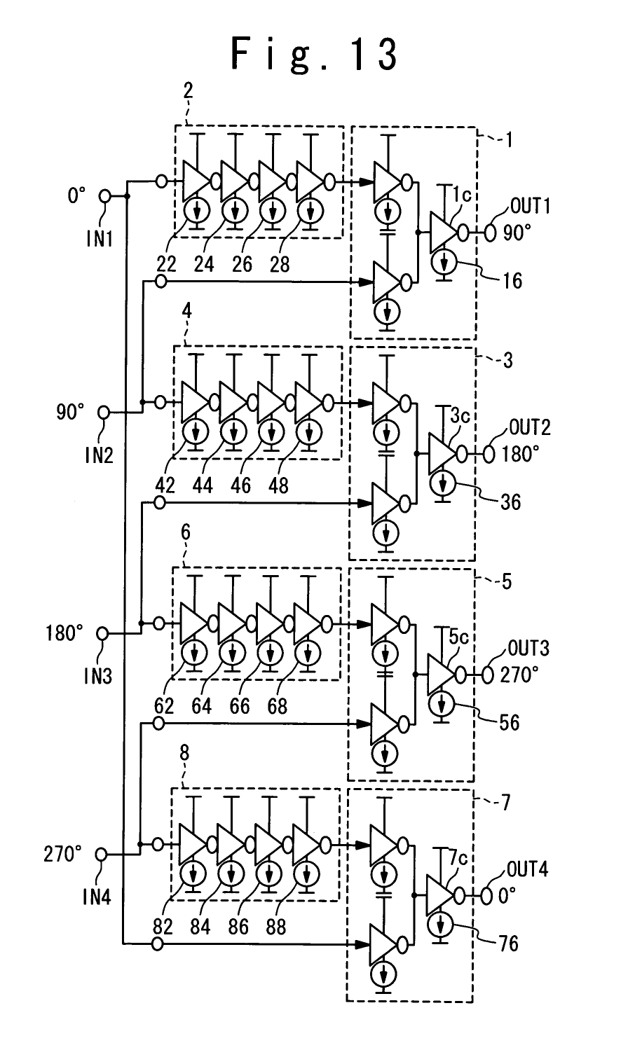

In another alternative embodiment, as shown in FIG. 13, the constant current sources between the output inverters and the power supply, denoted by numerals 15, 35, 55, and 75, may be removed from the phase blender circuits 1, 3, 5, and 7 in place of the constant current sources 16, 36, 56, and 76. Although being ineffective for regulating the rise times of the output inverters 1c, 3c, 5c, and 7c, this architecture still effectively regulates the fall times, and thereby stabilizes the delay times of the phase blender circuits 1, 3, 5, and 7.

### Fourth Embodiment

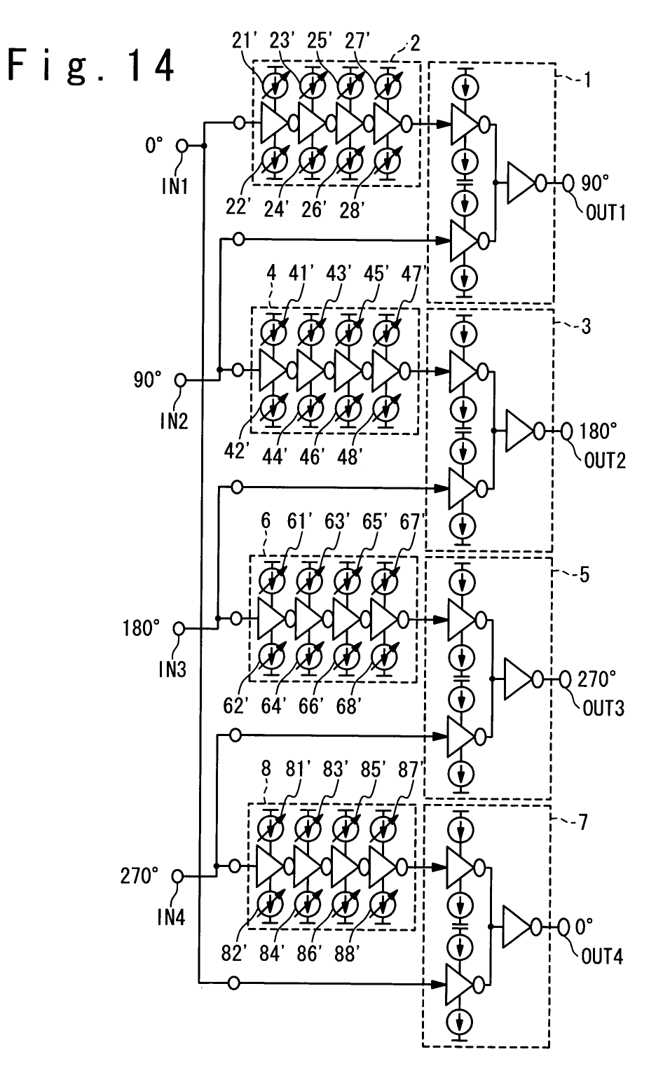

In a fourth embodiment, as shown in FIG. 14, variable current sources, denoted by numerals 21′ to 28′, 41′ to 48′, 61′ to 68′, and 81′ to 88′, are additionally connected to the power and ground terminals of the serial-connected inverters within the delay lines 2, 4, 6, and 8. The variable current sources 21′ to 28′, 41′ to 48′, 61′ to 68′ and 81′ to 88′ effectively regulates the rise/fall times of the serial-connected inverters within the delay lines 2, 4, 6, and 8, and thereby stabilize the delay times of the delay lines 2, 4, 6, and 8.

Additionally, the variable current sources 21′ to 28′, 41′ to 48′, 61′ to 68′, and 81′ to 88′ make the delay times of the delay lines 2, 4, 6, and 8 adjustable by controlling the pull-up and pull-down currents through the serial-connected inverters, and thereby allow the phase interpolator circuitry in this embodiment to be adapted to operate at various frequencies. It should be noted that the change in the operation frequency requires the delay lines 2, 4, 6, and 8 to be modified with the delay times thereof to provide the required phase delay of 90°. For instance, The delay times of the delay lines 2, 4, 6, and 8 are needed to be variable between 160 and 200 picoseconds when the operation frequency ranges between 1.25 and 1.56 GHz.

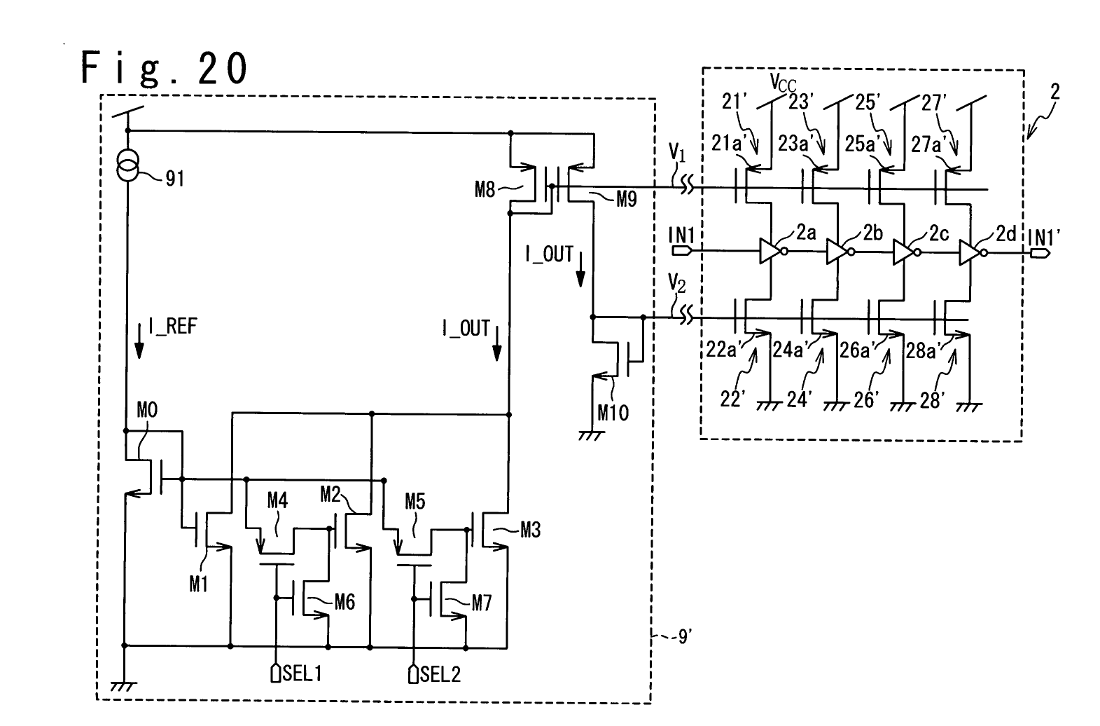

FIG. 20 illustrates an exemplary architecture of the variable current sources 21′ to 28′. The constant current sources 21′, 23′, 25′, and 27′respectively include PMOS transistors 21a′, 23a′, 25a′, and 27a ′ whose gate voltages are regulated to a control voltage V₁, while the constant current sources 22′, 24′, 26′, and 28′ include NMOS transistors 22a′, 24a′, 26a′, and 28a′ whose gate voltages are regulated to a control voltage V₂. The PMOS transistors 21a′, 23a′, 25a′, and 27a′ are connected between power supplies and the inverters 2a, 2b, 2c, and 2d, and the NMOS transistors 22a′, 24a′, 26a′, and 28a′ are connected between ground and the inverters 2a, 2b, 2c, and 2d.

The control voltages V₁ and V₂ are developed by a variable voltage source 9′ which is responsive to select signals SEL1 and SEL2 to develop the control voltages V₁ and V₂. The variable voltage source 9 includes a constant current source 91, NMOS transistors MO, M1, M2, M3, M6, M7, M10, and PMOS transistors M4, M5, M8, and M9. NMOS transistors MO, M1, M2, and M3 function as a current mirror whose output current I_OUT is variable. The NMOS transistor M4, M5, M6, and M7 are used for selecting NMOS transistor M2, and M3 in response to the select signals SEL1, and SEL2. The PMOS transistor M8 is used for providing the control voltage V₁ for the PMOS transistors 21a′, 23a′, 25a′, and 27a′. The PMOS transistor M8 and the PMOS transistors 21a′, 23a′, 25a′, and 27a′operate as current mirrors which provide the pull-up currents for the inverters 2a to 2d so that the pull-up currents are identical to the current I_OUT. The PMOS transistor M8 is also used to constitute a current mirror with the PMOS transistor M9 to develop a current identical to the output current I_OUT. The NMOS transistor M10 is used for providing the control voltage V₂ for the NMOS transistors 22a′, 24a′, 26a′, and 28a′. The NMOS transistor M10 and the NMOS transistors 22a′, 24a′, 26a′, and 28a′ operate as current mirrors which provide the pull-down currents for the inverters 2a to 2d so that the pull-down currents are identical to the current I_OUT.

The variable voltage source 9′ controls the pull-up and pull-down currents, which are identical to the output current I_OUT, in response to the select signals SEL1 and SEL2. Consider the case that the operation frequency of the multiphase clock delivery circuit is selectable from three frequencies, 1.25 GHz, 1.35 GHz, and 1.56 GHz, which respectively require pull-up and pull-down currents of X, Y, Z (mA) through the inverters 2a to 2d, where X<Y<Z. In this case, the NMOS transistors M1, M2, and M3 are designed to have drive abilities so that the NMOS transistors M1, M2, and M3 drive currents of X (mA), Y-X (mA), and Z-Y (mA), respectively; the drive abilities may be adjusted by adjusting the gate widths of the NMOS transistors M1, M2, and M3. When the operation frequency is set to 1.25 GHz, both of the select signals SEL1 and SEL2 are deactivated to activate only the NMOS transistor M1. Only the NMOS transistor M1 is used for developing the output current I_OUT, and this results in that the output current I_OUT is regulated to X (mA). This achieves the pull-up and pull-down currents through the inverters 2a to 2d are adjusted to X (mA). For the operation frequency of 1.35 GHz, the NMOS transistors M1 and M2 are selected through activating the select signal SEL1 with the select signal SEL2 deactivated. This results in that the pull-up and pull-down currents are regulated to Y (mA). Correspondingly, for the operation frequency of 1.56 GHz, all of the NMOS transistors M1, M2 and M3 are selected through activating both of the select signals SEL1 and SEL2. This results in that the pull-up and pull-down currents are regulated to Z (mA).

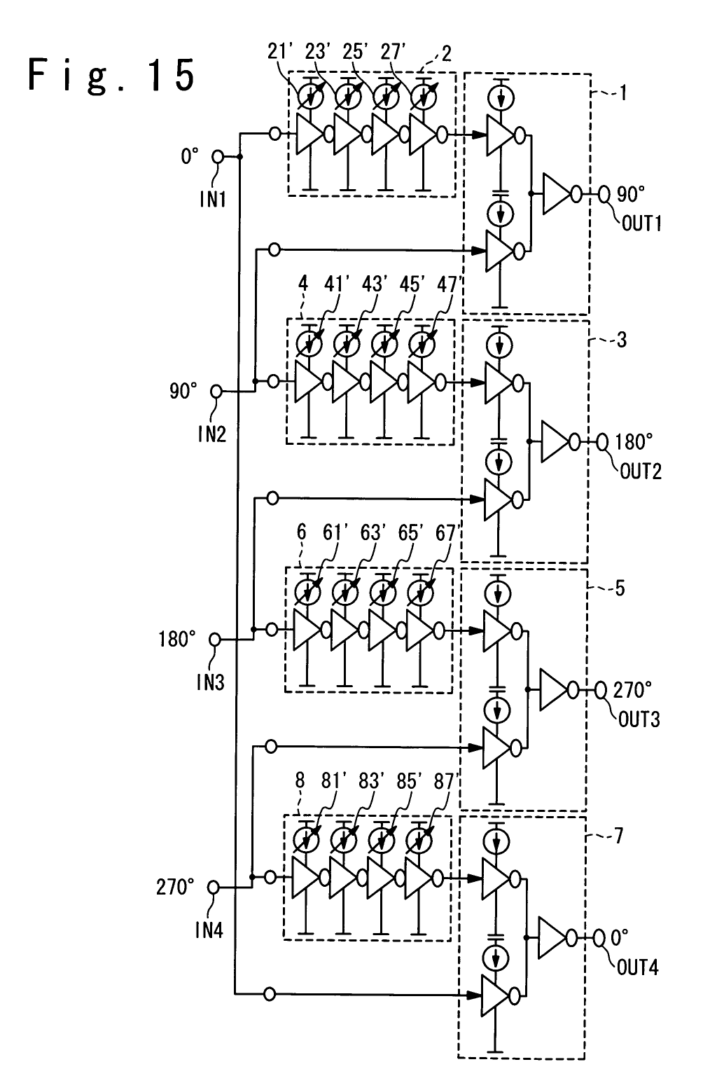

In an alternative embodiment, as shown in FIG. 15, the constant current sources between the serial-connected inverters and ground, denoted by the numerals 22′, 24′, 26′, 28′, 42′, 44′, 46′, 48′, 62′, 64′, 66′, 68′, 82′, 84′, 86′, and 88′, may be removed from the delay lines 2, 4, 6, and 8. Although being ineffective for regulating the fall times, this architecture effectively regulates the rise times of the serial-connected inverters, and thereby stabilizes the delay times of the delay lines 2, 4, 6, and 8.

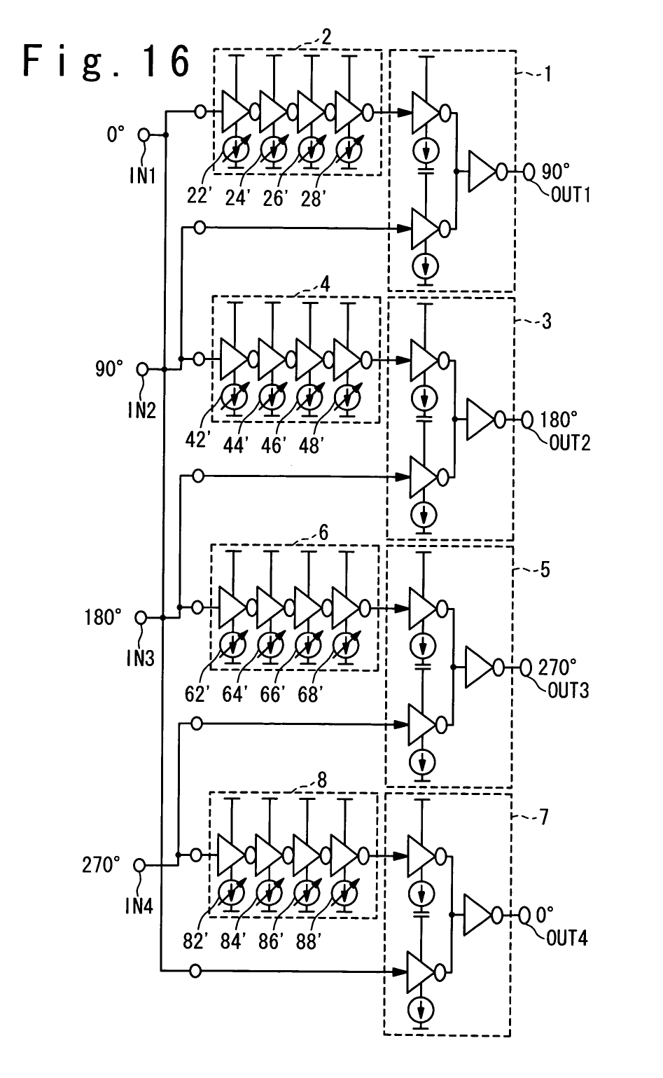

In another alternative embodiment, as shown in FIG. 16, the constant current sources between the serial-connected inverters and the power supply, denoted by the numerals 21′, 23′, 25′, 27′, 41′, 43′, 45′, 47′, 61′, 63′, 65′, 67′, 81′, 83′, 85′, and 87′, may be removed from the delay lines 2, 4, 6, and 8 in place of the constant current sources 22′, 24′, 26′, 28′, 42′, 44′, 46′, 48′, 62′, 64′, 66′, 68′, 82′, 84′, 86′, and 88′. Although being ineffective for regulating the rise times of the serial-connected inverters, this architecture still effectively regulates the fall times, and thereby stabilizes the delay times of the delay lines 2, 4, 6, and 8.

### Fifth Embodiment

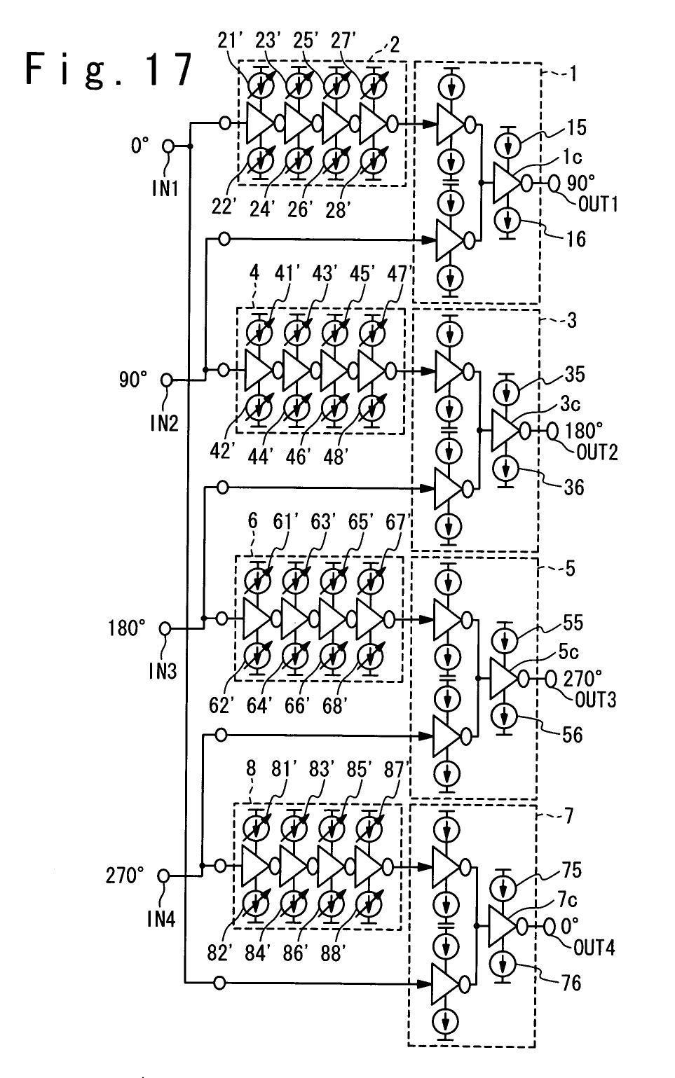

In a fifth embodiment, the multiphase clock delivery circuit shown in FIG. 17 is modified so that each of the phase blender circuits 1, 3, 5, 7 additionally include a pair of constant current sources, one disposed between the power terminal of the output inverter and the power supply, and the other between the ground terminal and ground; the constant current sources connected to the power terminals of the output inverters are denoted by numerals 15, 35, 55, and 75, and the constant current sources connected to the ground terminals are denoted by numerals 16, 36, 56, and 76.

As described in the third embodiment, the additional constant current sources 15, 16, 35, 36, 55, 56, 75, and 76 effectively regulate the rise/fall times of the output inverters 1c, 3c, 5c, and 7c within the phase blender circuit 1, 3, 5, and 7, and thereby stabilize the delay times of the phase blender circuit 1, 3, 5, and 7 against the undesirable manufacture variance and the changes in the operation temperature and the power supply voltage. This effectively reduces the clock skews between the output clock signals OUT1 to OUT4.

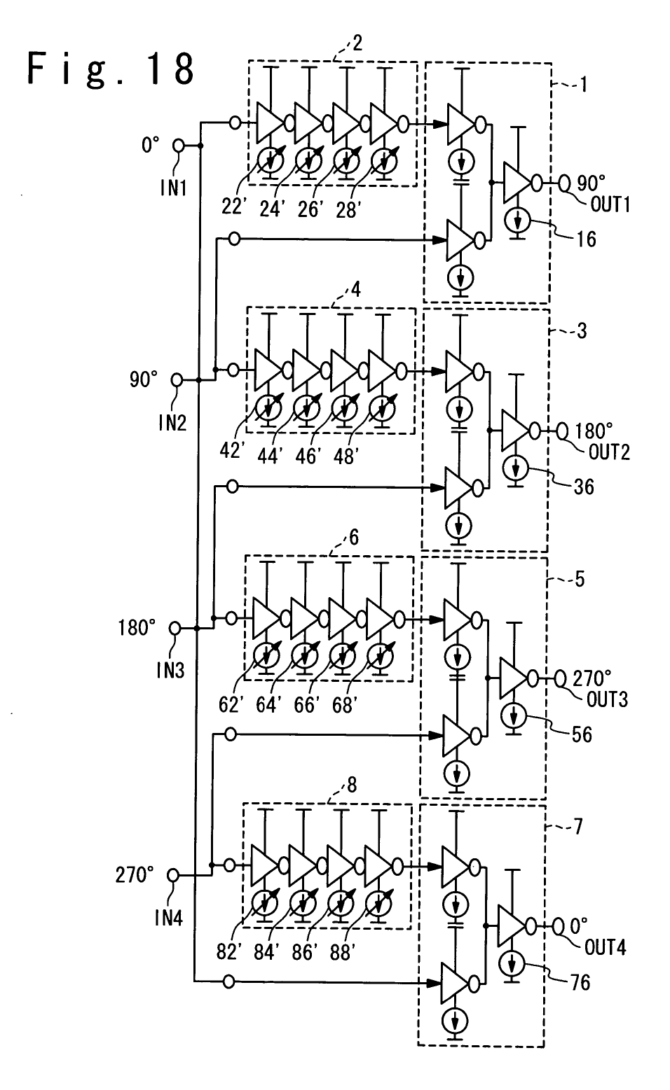

In an alternative embodiment, as shown in FIG. 18, the constant current sources between the output inverters and ground, denoted by numerals 16, 36, 56, and 76, may be removed from the phase blender circuits 1, 3, 5, and 7. Although being ineffective for regulating the fall times of the output inverters 1c, 3c, 5c, and 7c, this architecture still effectively regulates the rise times, and thereby stabilizes the delay times of the phase blender circuits 1, 3, 5, and 7.

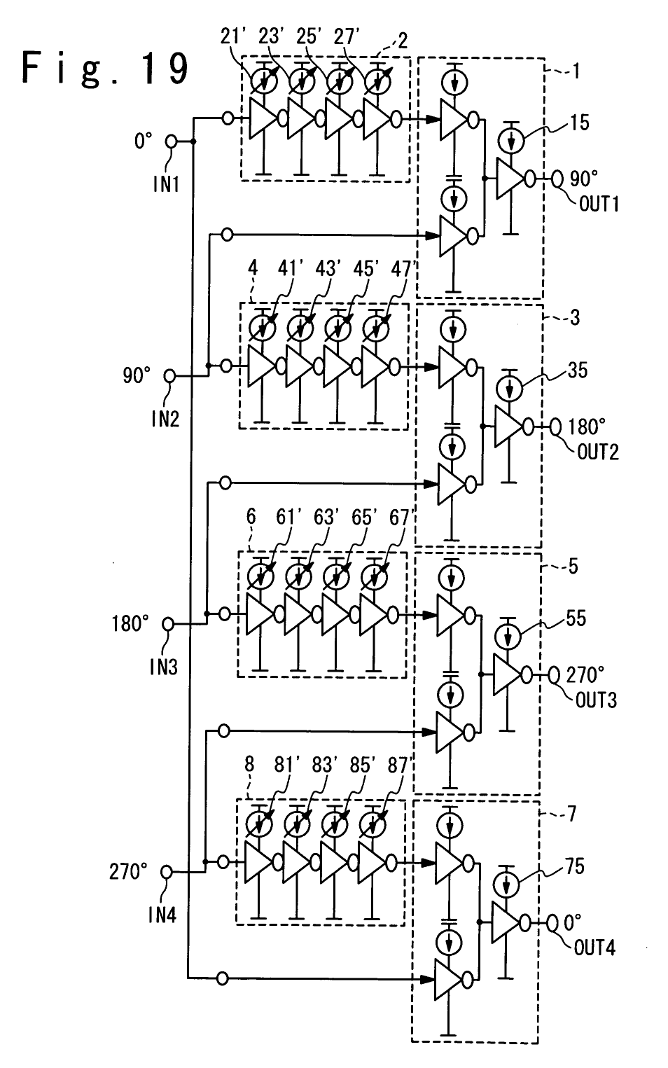

In another alternative embodiment, as shown in FIG. 19, the constant current sources between the output inverters and the power supply, denoted by numerals 15, 35, 55, and 75, may be removed from the phase blender circuits 1, 3, 5, and 7 in place of the constant current sources 16, 36, 56, and 76. Although being ineffective for regulating the rise times of the output inverters 1c, 3c, 5c, and 7c, this architecture still effectively regulates the fall times, and thereby stabilizes the delay times of the phase blender circuits 1, 3, 5, and 7.

Although the invention has been described in its preferred form with a certain degree of particularity, it is understood that the present disclosure of the preferred form has been changed in the details of construction and the combination and arrangement of parts may be resorted to without departing from the scope of the invention as hereinafter claimed.

1. A phase interpolator circuitry comprising:
a delay line delaying a first input clock signal to develop a delayed clock signal; and
a phase blender circuit including:
a first inverter receiving said delayed input clock signal, and
a second inverter receiving a second input clock signal phased away from said first input clock signal, outputs of said first and second inverters being commonly coupled together; and
at least one of first to fourth constant current sources,
wherein said first constant current source is connected between a power terminal of said first inverter and a power supply,
wherein said second constant current source is connected between a ground terminal of said first inverter and ground,
wherein said third constant current source is connected between a power terminal of said second inverter and a power supply, and
wherein said fourth constant current source is connected between a ground terminal of said second inverter and ground.

2. The phase interpolator circuitry according to claim 1, wherein said first constant current source develops a pull-up current through said first inverter so that a rise time of said first inverter is increased compared to an intrinsic rise time of said first inverter.

3. The phase interpolator circuitry according to claim 1, wherein said second constant current source develop a pull-down current through said first inverter so that a fall time of said first inverter is increased compared to an intrinsic fall time of said first inverter.

4. The phase interpolator circuitry according to claim 1, wherein said third constant current source develops a pull-up current through said second inverter so that a rise time of said second inverter is increased compared to an intrinsic rise time of said second inverter.

5. The phase interpolator circuitry according to claim 1, wherein said fourth constant current source develops a pull-down current through said second inverter so that a fall time of said second inverter is increased compared to an intrinsic fall time of said second inverter.

6. The phase interpolator circuitry according to claim 1, wherein said first constant current source has a drive ability smaller than that of a pull-up transistor within said first inverter.

7. The phase interpolator circuitry according to claim 1, wherein said second constant current source has a drive ability smaller than that of a pull-down transistor within said first inverter.

8. The phase interpolator circuitry according to claim 1, wherein said third constant current source has a drive ability smaller than that of a pull-up transistor within said second inverter.

9. The phase interpolator circuitry according to claim 1, wherein said fourth constant current source has a drive ability smaller than that of a pull-down transistor within said second inverter.

10. The phase interpolator circuitry according to claim 1, wherein said delay line includes:
series-connected inverters, and
pull-up constant current sources respectively connected between power terminals of said series-connected inverters and a power supply.

11. The phase interpolator circuitry according to claim 10, wherein said pull-up constant current sources develop pull-up currents through said series-connected inverters, respectively, and
wherein said pull-up currents are variable.

12. The phase interpolator circuitry according to claim 1, wherein said delay line includes:
series-connected inverters, and
pull-down constant current sources respectively connected between ground terminals of said series-connected inverters and ground.

13. The phase interpolator circuitry according to claim 12, wherein said pull-down constant current sources develop pull-down currents through said series-connected inverters, respectively, and
wherein said pull-down currents are variable.

14. The phase interpolator circuitry according to claim 1, wherein said phase blender circuit further includes:
a third inverter having an input connected to said commonly coupled outputs of said first and second inverters, and
a fifth constant current source connected between a power terminal of said third inverter and a power supply.

15. The phase interpolator circuitry according to claim 1, wherein said phase blender circuit further includes:
a third inverter having an input connected to said commonly coupled outputs of said first and second inverters, and
a sixth constant current source connected between a ground terminal of said third inverter and ground.

16. The phase interpolator circuitry according to claim 1, wherein said first and second input clock signals are phased from each other by 360°/2ⁿ, being an integer.
